(19) United States
(12) Patent Application Publication
(10) Pub. No.: US 2026/0006930 A1
(43) Pub. Date: Jan. 1, 2026

(54) IMAGE SENSOR AND METHOD FOR MAKING THE SAME

(71) Applicant: Shanghai Huali Microelectronics Corporation, Shanghai (CN)

(72) Inventors: Chunyan YANG, Shanghai (CN); Chenchen QIU, Shanghai (CN); Hui CHEN, Shanghai (CN)

(21) Appl. No.: 18/885,265

(22) Filed: Sep. 13, 2024

(30) Foreign Application Priority Data
Jun. 28, 2024 (CN) 202410867374.7

(51) Int. Cl. H01L 27/146

(52) U.S. Cl. CPC H10F 39/806; H10F 39/024

(57) ABSTRACT

The present application discloses a cell structure of an image sensor, comprising: a semiconductor substrate, and a photoelectric conversion diode formed in the semiconductor substrate. More than one grooves are formed in a back region of the semiconductor substrate, and the grooves have cross sections in a triangle shape or an inverted trapezoid shape with a downward apex. The grooves are filled with a first dielectric layer having a refractive index less than that of the semiconductor substrate. The first dielectric layer filled in the grooves forms an optical path increasing structure for increasing an effective optical path of back incoming light. The grooves have sides along a first crystalline surface of the semiconductor substrate, and the first crystalline surface is a stop surface for anisotropic etching of the semiconductor substrate. The present application also discloses a method of making an image sensor.

### CROSS-REFERENCES TO RELATED APPLICATIONS

This application claims priority to Chinese patent application No. CN202410867374.7, filed on Jun. 28, 2024, the disclosure of which is incorporated herein by reference in its entirety.

### TECHNICAL FIELD

The present application relates to the field of semiconductor integrated circuit manufacture, and in particular to an image sensor. The present application also relates to a method of making the image sensor.

### BACKGROUND

A single photon avalanche diode (SPAD) sensor is a sensor in which a PN junction is used to receive external light to generate electron-hole pairs, they are accelerated by high reverse bias voltages and collide with crystal lattices to generate more electron-hole pairs, resulting in an avalanche effect, and ultimately a large current is outputted. SPAD sensors with high resolution and for small-pixel images are increasingly demanded with growing demands of image quality. However, ever-shrinking pixel sizes affect photon absorption, thereby degrading imaging quality. Therefore, small-size SPAD sensors have an important characterization parameter, photon detection efficiency (PDE).

Existing SPAD sensors with back planar structures have low photon detection efficiency. Referring to FIG. 1, it is a structural schematic diagram of an existing SPAD sensor when photon detection is performed. The SPAD sensor has a cell structure 101 having a photodiode to which a large bias voltage can be applied and which generates an avalanche breakdown region. The cell structure 101 has a microlens 102 at a back thereof for converging light to allow more light to enter the light detection region of the photodiode. In FIG. 1, an arrow line 103 indicates the route of incoming light. It can be seen that the microlens 102 has a converging effect on light to allow more light from the outside to enter the light detection region of the photodiode, but the range of the route region of the incoming light becomes small in the light detection region of the photodiode. In FIG. 1, the region 104 indicates the route region of the incoming light, which route region corresponds to a photovoltaic conversion volume. A relatively small range of the route region of the incoming light reduces the effective optical path of the incoming light. For near-infrared light with a relatively long wavelength, a reduced effective optical path and a small photoelectric conversion volume reduce actual light absorption, so as to reduce the photon detection efficiency.

### BRIEF SUMMARY

According to some embodiments in this application, an image sensor having a cell structure comprising:
a semiconductor substrate; and
a photoelectric conversion diode formed in the semiconductor substrate;
wherein more than one grooves are formed in a back region of the semiconductor substrate, and the grooves have cross sections in a triangle shape or an inverted trapezoid shape with a downward apex;
the grooves are filled with a first dielectric layer having a refractive index less than that of the semiconductor substrate;
the first dielectric layer filled in the grooves forms an optical path increasing structure for increasing an effective optical path of back incoming light; and
the grooves have sides along a first crystalline surface of the semiconductor substrate, and the first crystalline surface is a stop surface for anisotropic etching of the semiconductor substrate.

In some examples, the grooves are uniformly distributed in the back of the semiconductor substrate in the cell structure; and the cross section of the semiconductor substrate between the grooves is in a triangle shape or a square trapezoid shape with an upward apex.

In some examples, the semiconductor substrate comprises a silicon substrate.

In some examples, the material of the first dielectric layer comprises silicon dioxide.

In some examples, deep trench isolation (DTI) is provided at a peripheral side of the cell structure.

In some examples, the sides of the grooves are along the (111) crystal surface of the silicon substrate when the semiconductor substrate is a silicon substrate.

In some examples, the image sensor is an SPAD sensor.

In some examples, the photoelectric conversion diode comprises:
a first electrode region comprising a doped region with a first conductive type; and
a second electrode region comprising a heavily doped region with a second conductive type formed in a selected region of a top region of the doped region with a first conductive type;
wherein the second electrode region is connected to a second electrode consisting of a frontal metal layer by a contact hole; and
a heavily doped lead-in region with a first conductive type is formed in a selected region of a top region of the first electrode region, and the lead-in region is connected to a first electrode consisting of a frontal metal layer by a contact hole.

To solve the above technical problem, the present application provides a method of making an image sensor, comprising the steps of:
achieving a front-side process on a semiconductor substrate, wherein it comprises forming a photoelectric conversion diode of each cell structure of an image sensor in the semiconductor substrate;
performing back-side thinning for the semiconductor substrate;
forming grooves in the back region of the semiconductor substrate, wherein each cell structure comprises more than one grooves having cross sections in a triangle shape or an inverted trapezoid shape with a downward apex; the grooves have sides along a first crystalline surface of the semiconductor substrate, and the first crystalline surface is a stop surface for anisotropic etching of the semiconductor substrate; and
filling the grooves with a first dielectric layer having a refractive index less than that of the semiconductor substrate, wherein the first dielectric layer filled in the grooves forms an optical path increasing structure for increasing an effective optical path of back incoming light.

In some examples, the grooves are uniformly distributed in the back of the semiconductor substrate in the cell structure; and the cross section of the semiconductor substrate between the grooves is in a triangle shape or a square trapezoid shape with an upward apex.

In some examples, the semiconductor substrate comprises a silicon substrate.

In some examples, the sub-step of forming the grooves comprises:
forming a first mask layer, and patterning the first mask layer to define a region for forming the grooves;
performing first etching for a back region of the semiconductor substrate by using the first mask layer as a mask to form an initial groove having a cross section structure in an inverted trapezoid shape or a U shape; and
performing second anisotropic wet etching to expand the initial grooves to form the grooves.

In some examples, an etching solution employed for the second wet etching comprises potassium hydroxide when the semiconductor substrate is a silicon substrate; and the sides of the grooves are along the (111) crystalline surface of the silicon substrate.

In some examples, the material of the first dielectric layer comprises silicon dioxide.

In some examples, after the back thinning is achieved and before forming the grooves, the method further comprises:
forming deep trench isolation at a peripheral side of the cell structure.

In some examples, the image sensor is an SPAD sensor.

In some examples, the photoelectric conversion diode comprises:
a first electrode region comprising a doped region with a first conductive type; and
a second electrode region comprising a heavily doped region with a second conductive type formed in a selected region of a top region of the doped region with a first conductive type;
wherein the second electrode region is connected to a second electrode consisting of a frontal metal layer by a contact hole; and
a heavily doped lead-in region with a first conductive type is formed in a selected region of a top region of the first electrode region, and the lead-in region is connected to a first electrode consisting of a frontal metal layer by a contact hole.

In the present application, grooves are provided in the back region of the semiconductor substrate and filled with the first dielectric layer having a lower refractive index; since the groves are in a triangular shape or an inverted trapezoid shape with a downward apex, the form of first dielectric layer is in an inverted pyramid shape; and the first dielectric layer in an inverted pyramid shape and with a refractive index lower than that of the semiconductor substrate can change a route of back incoming light, and thus the back incoming light has more distribution angles to increase a distribution region thereof in the depletion region of the photoelectric conversion diode, thereby increasing the effective optical path of the back incoming light, which also effectively increases the volume for actual photoelectric conversion, and thus increasing the photon detection efficiency, especially for near-infrared-wavelength photons.

The present application can be well suitable for the SPAD sensor to increase the photon detection efficiency thereof.

The sides of the grooves in the present application are obtained by anisotropic etching of a stop surface of a semiconductor substrate, and the application enables a simple, accurately controlled process, which facilitates to reduce a process cost and ensure good process quality.

### BRIEF DESCRIPTION OF THE DRAWINGS

The present application is described in further detail below in conjunction with figures and detailed description:

FIG. 1 is a structural schematic diagram of an existing SPAD sensor when photon detection is performed;

FIG. 2 is a structural schematic diagram of an image sensor of an embodiment of the present application;

FIG. 3 is a structural schematic diagram of an image sensor of an embodiment of the present application when photon detection is performed; and

FIGS. 4A-FIG. 4E are structural schematic diagrams of a device in each step of a method of making an image sensor of an embodiment of the present application.

### DETAILED DESCRIPTION OF THE DISCLOSURE

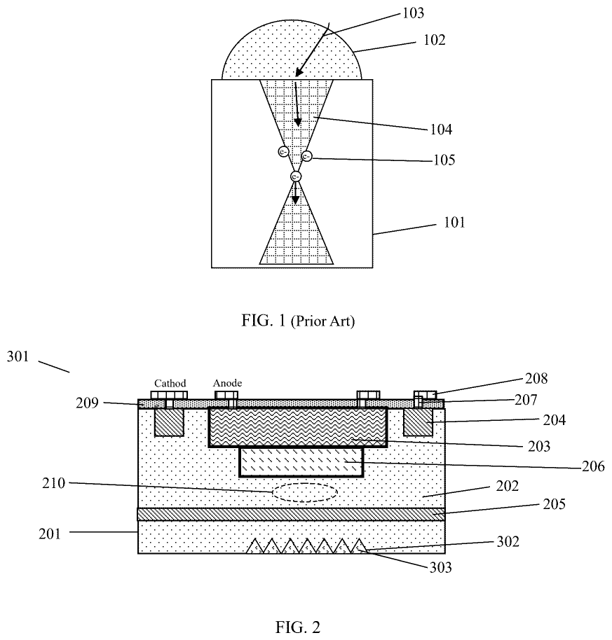

Referring to FIG. 2, it is a structural schematic diagram of an image sensor of an embodiment of the present application. A cell structure 301 of an image sensor of an embodiment of the present application comprises:
a semiconductor substrate 201; and
a photoelectric conversion diode formed in the semiconductor substrate 201.

More than one grooves 302 are formed in a back region of the semiconductor substrate 201, and the grooves 302 have cross sections in a triangle shape with a downward apex. In other embodiments, the grooves 302 may have cross sections in an inverted trapezoid shape. In the application, an inverted trapezoid is a trapezoid in which a length of a top edge is greater than that of a bottom edge; and a normal trapezoid is a trapezoid in which a length of a top edge is less than that of a bottom edge.

The grooves 302 are filled with a first dielectric layer 303 having a refractive index less than that of the semiconductor substrate 201.

The first dielectric layer 303 filled in the grooves 302 forms an optical path increasing structure for increasing an effective optical path of back incoming light. As can be seen from FIG. 2, during practice use, the back of the shown semiconductor substrate 201 is upward, so, the first dielectric layer 303 filled in the grooves 302 is in an inverted pyramid structure.

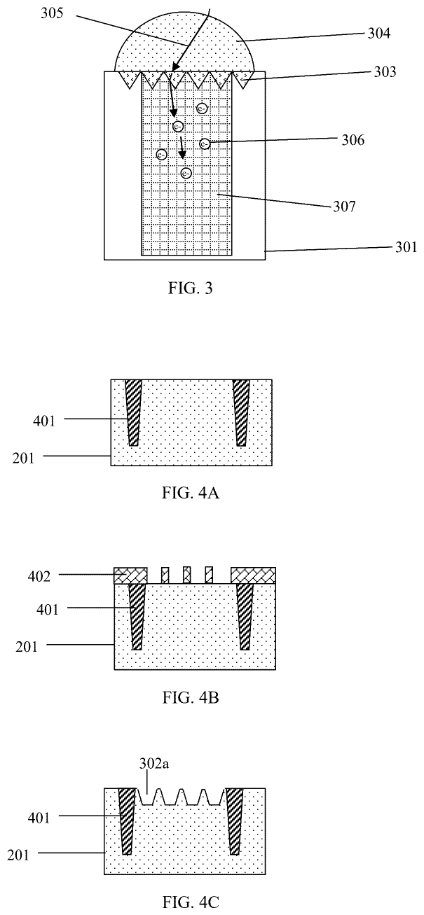

The working principle of the first dielectric layer 303 as an optical path increasing structure is further explained below. Referring to FIG. 3, it is a structural schematic diagram of an image sensor of an embodiment of the present application when photon detection is performed. The arrowed line 305 in FIG. 3 represents an incoming route of a beam of incoming light. It can be seen that the incoming light first passes through a microlens 304 which has a converging effect on the incoming light. However, after the incoming light is refracted by the top surface and side of the first dielectric layer 303, the incoming light entering the first semiconductor substrate 201 is more diffused, i.e., the incoming light can enter the semiconductor substrate 201 at more angles. Since the semiconductor substrate 201 has the photoelectric converter diode provided therein, the photoelectric converter diode can receive the incoming light in a larger depletion region and perform photoelectrical conversion to form photon-generated carriers such as photon-generated electrons 306. Also, the photon-generated carriers can move in a relatively large range (a long drift distance) by the reverse bias voltage from the photoelectric converter diode, thus generating more times of avalanche breakdown, and forming more photon-generated carriers, which improves the photon detection efficiency. Therefore, the embodiment of the present application can finally increase the effective optical path of back incoming light and improve the photon detection efficiency. Compared with FIG. 1, it can be seen that the region reached by the incoming light in FIG. 1 is the region corresponding to the reference number 104, and the region reached by the incoming light in FIG. 3 is the region corresponding to the reference number 307, and the region corresponding to the reference number 307 in FIG. 3 is larger than the region corresponding to the reference number 104 in FIG. 1. Therefore, the embodiment of the present application can increase the effective optical path.

The sides of the grooves 302 are along a first crystalline surface of the semiconductor substrate 201, and the first crystalline surface is a stop surface for anisotropic etching of the semiconductor substrate 201. Having the first crystalline surface as a stop surface for anisotropic etching of the semiconductor substrate 201, the sides of the grooves 302 can be obtained by anisotropic etching, facilitating precise control of the sides of the grooves 302, and the process cost can be reduced.

In embodiments of the present application, the grooves 302 are uniformly distributed in the back of the semiconductor substrate 201 in the cell structure 301; and the cross sections of the semiconductor substrate 201 between the grooves 302 is in a triangle shape with an upward apex. In other embodiments, the cross sections of the semiconductor substrate 201 between the grooves 302 may be in a normal trapezoid shape.

In embodiments of the present application, the effective range of back incoming light can be maximized the structure in which the cross sections of the grooves 302 are in a triangle shape with a downward apex and the cross section of the semiconductor substrate 201 between grooves 302 is in a triangle shape with an upward apex.

In embodiments of the present application, the semiconductor substrate 201 is a silicon substrate. In other embodiments, the semiconductor substrate 201 can also be other semiconductor material, such as germanium.

The material of the first dielectric layer 303 comprises silicon dioxide.

Deep trench isolation is provided at a peripheral side of the cell structure 301. The deep trench isolation prevents crosstalk such as optical or electrical crosstalk between adjacent cell structures 301.

In an embodiment of the present application, the sides of the grooves 302 are along the (111) crystal surface of the silicon substrate. When anisotropic etching is performed on the silicon substrate, an etching rate for the (111) crystalline surface can be minimized such that the etching stops at the (111) crystalline surface to form the sides of the grooves 302.

In embodiments of the present application, the image sensor is an SPAD sensor. The SPAD sensor has a photoelectric conversion diode which can produce avalanche breakdown by reverse bias voltages in addition to absorbing photons and generating photon-generated carriers, so that the number of carriers generated is multiplied.

The photoelectric conversion diode comprises:
a first electrode region comprising a doped region with a first conductive type. In embodiments of the present application, a doped epitaxial layer 202 with a first conductive type is also formed on the front side of the semiconductor substrate 201, the doped region with a first conductive type in the first electrode region consists of the epitaxial layer 202.

A buried layer 205 heavily doped with a first conductive type is also formed between the semiconductor substrate 201 and the epitaxial layer 202.

The semiconductor substrate 201 is doped with the first conductive type. In other embodiments, the doped region with a first conductive type of the first electrode region consists of formed on the semiconductor substrate 201.

The photoelectric conversion diode comprises a second electrode region 203 comprising a heavily doped region with a second conductive type formed in a selected region of a top region of the doped region with a first conductive type.

In embodiments of the present application, a lightly doped injection region 206 with a first conductive type is also formed in the epitaxial layer 202 at the bottom of the second electrode region 203.

The second electrode region 203 is connected to a second electrode consisting of a frontal metal layer 208 by a contact hole 207.

A heavily doped lead-in region 204 with a first conductive type is formed in a selected region of a top region of the first electrode region, and the lead-in region 204 is connected to the first electrode consisting of the frontal metal layer 208 by the contact hole 207.

In the embodiment of the application, the first conductive type is N-type and the second conductive type is P-type. The first electrode is a cathode and the second electrode is an anode. In other embodiments, the first conductive type may be P-type and the second conductive type may be N-type. The first electrode is an anode and the second electrode is a cathode.

During photon detection, the photoelectric conversion diode forms a depletion region by adding reverse bias voltages to the first electrode and second electrode, and the depletion region is mainly in the first electrode region, wherein the region shown by the dashed line box 210 is an avalanche breakdown region, and photon-generated carriers are prone to avalanche breakdown in the avalanche breakdown region.

In the embodiment of the present application, grooves 302 are provided in the back region of the semiconductor substrate 201 and are filled with the first dielectric layer 303 with a lower refractive index; since the groves 302 are in a triangular shape or an inverted trapezoid shape with a downward apex, the form of the first dielectric layer is in an inverted pyramid shape; and the first dielectric layer in an inverted pyramid shape and with a refractive index lower than that of the semiconductor substrate 201 can change a route of back incoming light, and thus the back incoming light has more distribution angles to increase a distribution region thereof in the depletion region of the photoelectric conversion diode, thereby increasing the effective optical path of the back incoming light, which also effectively increases the volume for actual photoelectric conversion, and thus increasing the photon detection efficiency, especially for near-infrared-wavelength photons.

The embodiment of the present application can be well suitable for the SPAD sensor to increase the photon detection efficiency thereof.

The sides of the grooves 302 in the embodiment of the present application are obtained by anisotropic etching of a stop surface of the semiconductor substrate 201, and the application enables a simple, accurately controlled process, which facilitates to reduce a process cost and ensure good process quality.

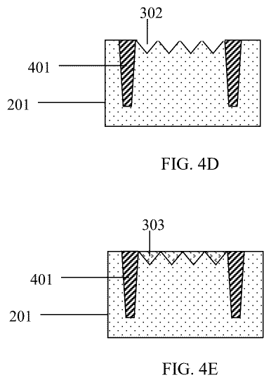

Referring to FIGS. 4A to 4E, they are structural schematic diagrams of a device in each step of a method of making an image sensor of an embodiment of the present application; and the method comprises:
step 1. achieving a front-side process on a semiconductor substrate 201, as described in FIG. 2, wherein it comprises forming a photoelectric conversion diode of each cell structure 301 of an image sensor in the semiconductor substrate 201.

In the embodiment method of the present application, the semiconductor substrate 201 is a silicon substrate. In other embodiment methods, the semiconductor substrate 201 can also be other semiconductor material, such as germanium.

In the embodiment method of the present application, the image sensor is an SPAD sensor.

The photoelectric conversion diode comprises:
a first electrode region comprising a doped region with a first conductive type. In the method of the embodiment of the present application, a doped epitaxial layer 202 with a first conductive type is also formed on the front side of the semiconductor substrate 201, the doped region with a first conductive type in the first electrode region consists of the epitaxial layer 202.

A buried layer 205 heavily doped with a first conductive type is also formed between the semiconductor substrate 201 and the epitaxial layer 202.

The semiconductor substrate 201 is doped with the first conductive type. In other embodiments of the method, the doped region with a first conductive type of the first electrode region consists of formed on the semiconductor substrate 201.

The photoelectric conversion diode comprises a second electrode region 203 comprising a heavily doped region with a second conductive type formed in a selected region of a top region of the doped region with a first conductive type.

In the method of the embodiment of the present application, a lightly doped injection region 206 with a first conductive type is also formed in the epitaxial layer 202 at the bottom of the second electrode region 203.

The second electrode region 203 is connected to a second electrode consisting of a frontal metal layer 208 by a contact hole 207.

A heavily doped lead-in region 204 with a first conductive type is formed in a selected region of a top region of the first electrode region, and the lead-in region 204 is connected to the first electrode consisting of the frontal metal layer 208 by the contact hole 207.

In the method of the embodiment of the present application, the first conductive type is N-type and the second conductive type is P-type. The first electrode is a cathode and the second electrode is an anode. In other embodiments, the first conductive type may be P-type and the second conductive type may be N-type. The first electrode is an anode and the second electrode is a cathode.

After achieving the front-side process, the wafer for the semiconductor substrate 201 is usually also bonded to another wafer on which a peripheral circuit is formed.

The method comprises step 2 of performing back-side thinning for the semiconductor substrate 201, referring to FIG. 4A.

The method of the embodiments of the present application further comprises, before subsequent formation of the grooves 302:
forming deep trench isolation 401 at a peripheral side of the cell structure 301.

The method comprises step 3 of forming grooves 302 in the back region of the semiconductor substrate 201, wherein each cell structure 301 comprises more than one grooves 302 having cross sections in a triangle shape with a downward apex. In the method of other embodiments, the cross sections of the grooves 302 are in an inverted trapezoid shape.

The sides of the grooves 302 are along a first crystalline surface of the semiconductor substrate 201, and the first crystalline surface is a stop surface for anisotropic etching of the semiconductor substrate 201.

In the method of embodiments of the present application, the grooves 302 are uniformly distributed in the back of the semiconductor substrate 201 in the cell structure 301; and the cross section of the semiconductor substrate 201 between the grooves 302 is in a triangular shape, or a normal trapezoid with an upward apex.

In the method of embodiments of the present application, the sub-step of forming the grooves 302 include:
referring to FIG. 4B, forming a first mask layer 402, and patterning the first mask layer 402 to define a region for forming the grooves 302.

In some embodiment methods, photoresist is used for the first mask layer 402; and a photolithography process is performed, i.e., the photoresist is exposed and developed to form a graphic of the first mask layer 402.

Referring to FIG. 4C, first etching is performed for a back region of the semiconductor substrate 201 by using the first mask layer 402 as a mask to form initial grooves 302a having a cross section structure in an inverted trapezoid shape or a U shape. In some embodiments, the first etching is performed by using dry etching.

Referring to FIG. 4D, second anisotropic wet etching is performed to expand the initial grooves 302a to form the grooves 302.

In some embodiments, an etching solution employed for the second wet etching comprises potassium hydroxide when the semiconductor substrate 201 is a silicon substrate, the sides of the grooves are along the (111) crystalline surface of the silicon substrate, and the potassium hydroxide solution enables a relatively large difference between the etching rate for the (111) crystalline surface of the silicon substrate and the etching rate for other crystalline surface of the silicon substrate, such as the (100) crystalline surface and (110) crystalline surface, so that the grooves 302 having a cross section in a triangular shape with a downward apex can be well formed.

The method comprises step 4 of, referring to FIG. 4E, filling the groove 302 with a first dielectric layer 303 having a refractive index less than that of the semiconductor substrate 201, wherein the first dielectric layer 303 filled in the grooves 302 forms an optical path increasing structure for increasing an effective optical path of back incoming light.

In some embodiments of the method, the material of the first dielectric layer 303 comprises silicon dioxide.

Then, the fabrication of the entire image sensor can be completed in conjunction with existing conventional back-side processes.

The application is described in detail above by specific embodiments without limitation to the application. Without departing from the principle of the present application, modifications and improvements may be made by those skilled in the art, which shall also be within the scope of protection of the present application.

What is claimed is:

1. An image sensor, wherein a cell structure comprises:
a semiconductor substrate; and
a photoelectric conversion diode formed in the semiconductor substrate;
wherein more than one grooves are formed in a back region of the semiconductor substrate, and the grooves have cross sections in a triangle shape or an inverted trapezoid shape with a downward apex;
the grooves are filled with a first dielectric layer having a refractive index less than that of the semiconductor substrate;
the first dielectric layer filled in the grooves forms an optical path increasing structure for increasing an effective optical path of back incoming light; and
the grooves have sides along a first crystalline surface of the semiconductor substrate, and the first crystalline surface is a stop surface for anisotropic etching of the semiconductor substrate.

2. The image sensor according to claim 1, wherein the grooves are uniformly distributed in the back of the semiconductor substrate in the cell structure; and the cross section of the semiconductor substrate between the grooves is in a triangle shape or a square trapezoid shape with an upward apex.

3. The image sensor according to claim 1, wherein the semiconductor substrate comprises a silicon substrate.

4. The image sensor according to claim 3, wherein the material of the first dielectric layer comprises silicon dioxide.

5. The image sensor according to claim 1, wherein deep trench isolation is provided at a peripheral side of the cell structure.

6. The image sensor according to claim 3, wherein the sides of the grooves are along the (111) crystal surface of the silicon substrate when the semiconductor substrate is a silicon substrate.

7. The image sensor according to claim 1, wherein the image sensor is an SPAD sensor.

8. The image sensor according to claim 7, wherein the photoelectric conversion diode comprises:
a first electrode region comprising a doped region with a first conductive type; and
a second electrode region comprising a heavily doped region with a second conductive type formed in a selected region of a top region of the doped region with a first conductive type;
wherein the second electrode region is connected to a second electrode consisting of a frontal metal layer by a contact hole; and
a heavily doped lead-in region with a first conductive type is formed in a selected region of a top region of the first electrode region, and the lead-in region is connected to a first electrode consisting of a frontal metal layer by a contact hole.

9. A method of making an image sensor, comprising the steps of:
achieving a front-side process on a semiconductor substrate, wherein it comprises forming a photoelectric conversion diode of each cell structure of an image sensor in the semiconductor substrate;
performing back-side thinning for the semiconductor substrate;
forming grooves in the back region of the semiconductor substrate, wherein each cell structure comprises more than one grooves having cross sections in a triangle shape or an inverted trapezoid shape with a downward apex; and the grooves have sides along a first crystalline surface of the semiconductor substrate, and the first crystalline surface is a stop surface for anisotropic etching of the semiconductor substrate; and
filling the grooves with a first dielectric layer having a refractive index less than that of the semiconductor substrate, wherein the first dielectric layer filled in the grooves forms an optical path increasing structure for increasing an effective optical path of back incoming light.

10. The method of making the image sensor according to claim 9, wherein the grooves are uniformly distributed in the back of the semiconductor substrate in the cell structure; and the cross section of the semiconductor substrate between the grooves is in a triangle shape or a square trapezoid shape with an upward apex.

11. The method of making the image sensor according to claim 9, wherein the semiconductor substrate comprises a silicon substrate.

12. The method of making the image sensor according to claim 11, wherein the sub-step of forming the grooves comprises:
forming a first mask layer, and patterning the first mask layer to define a region for forming the grooves;
performing first etching for a back region of the semiconductor substrate by using the first mask layer as a mask to form an initial groove having a cross section structure in an inverted trapezoid shape or a U shape; and
performing second anisotropic wet etching to expand the initial grooves to form the grooves.

13. The method of making the image sensor according to claim 12, wherein an etching solution employed for the second wet etching comprises potassium hydroxide when the semiconductor substrate is a silicon substrate; and the sides of the grooves are along the (111) crystalline surface of the silicon substrate.

14. The method of making the image sensor according to claim 11, wherein the material of the first dielectric layer comprises silicon dioxide.

15. The method of making the image sensor according to claim 9, after the back thinning is achieved and before forming the grooves, further comprising:
forming deep trench isolation at a peripheral side of the cell structure.

16. The method of making the image sensor according to claim 9, wherein the image sensor is an SPAD sensor.

17. A method of making the image sensor according to claim 16, wherein the photoelectric conversion diode comprises:
a first electrode region comprising a doped region with a first conductive type; and
a second electrode region comprising a heavily doped region with a second conductive type formed in a selected region of a top region of the doped region with a first conductive type;
wherein the second electrode region is connected to a second electrode consisting of a frontal metal layer by a contact hole; and
a heavily doped lead-in region with a first conductive type is formed in a selected region of a top region of the first electrode region, and the lead-in region is connected to a first electrode consisting of a frontal metal layer by a contact hole.
